(19) United States
(12) Patent Application Publication
(10) Pub. No.: US 2009/0273015 A1
(43) Pub. Date: Nov. 5, 2009

(54) NON-VOLATILE MEMORY CELL

(75) Inventor: Bohumil Lojek, Colorado Springs, CO (US)

Correspondence Address: FISH & RICHARDSON P.C., PO BOX 1022, MINNEAPOLIS, MN, 55440-1022, US

(73) Assignee: ATMEL CORPORATION, San Jose, CA (US)

(21) Appl. No.: 12/112,874

(22) Filed: Apr. 30, 2008

(51) Int. Cl. H01L 29/788; H01L 21/336

(52) U.S. Cl. 257/316; 438/257; 438/294; 257/E29.3; 257/E21.409

(57) ABSTRACT

This document discloses non-volatile memory cells and methods of manufacturing the same. The non-volatile memory cells are self-aligned and have a reduced tunnel window area that is within an active region of a substrate. The tunnel window area can be reduced using mask openings without optical proximity correction that define tunnels having one or more curvatures.

### BACKGROUND

This specification relates to non-volatile memory cells.

Electronic devices are being developed that offer more capabilities, utilize less power and can be manufactured in small packages. For example, portable computing devices have evolved into comprehensive data devices that integrate the features of phones, personal digital assistants (PDAs) and computers. As the capabilities of these devices increase, so do their memory and power requirements. The increasing memory requirements of electronic devices, coupled with shrinking power budgets and packaging dimensions, require memory devices that offer more storage, with lower power consumption, and smaller physical dimensions.

An electrically erasable programmable read only memory (EEPROM) cell is a particular non-volatile memory cell. EEPROM scaling is dependent on the size of the tunnel window that is defined for the device. The tunnel window directly impacts the dimensions of the gates that are required for the device. The gate dimensions, in turn, directly impact the space required for the memory cell. Accordingly, in some semiconductor devices, the size of the tunnel window may limit device density.

### SUMMARY

This document discloses non-volatile memory cells and methods of manufacturing the same. The non-volatile memory cells are self-aligned and have a reduced tunnel window area that is within an active region. The tunnel window area can be reduced using mask openings without optical proximity correction that define tunnels having one or more curvatures.

Particular implementations of the subject matter described in this specification can be implemented so as to realize one or more of the following advantages. One advantage realized is reduced leakage current associated with a memory transistor. Another advantage is increased scalability of non-volatile memory cells. Still another advantage is increased reliability of non-volatile memory cells. Yet another advantage is increased operating temperatures for non-volatile memory cells. These advantages can be separately realized or realized in combination in various implementations.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a cross-sectional view of an example self-aligned non-volatile memory cell.

FIG. 2A is a top view of an example semiconductor substrate having tunnel windows.

FIG. 2B is a cross-sectional view of an example non-volatile memory cell with spacers.

FIG. 2C is a top view of an example tunnel window having a perimeter that defines curvatures.

FIG. 2D is another top view of an example semiconductor substrate having tunnel windows.

FIGS. 3A-3L are cross-sectional views of an example memory cell at stages throughout an implementation of self-aligned non-volatile cell fabrication.

FIG. 4 is a flow chart illustrating an example process of manufacturing a non-volatile memory cell.

FIG. 5 is a flow chart illustrating an example process of forming a tunnel window having rounded edges.

Like reference numbers and designations in the various drawings indicate like elements.

### DETAILED DESCRIPTION

### I. Self-Aligned Non-Volatile Memory Cell

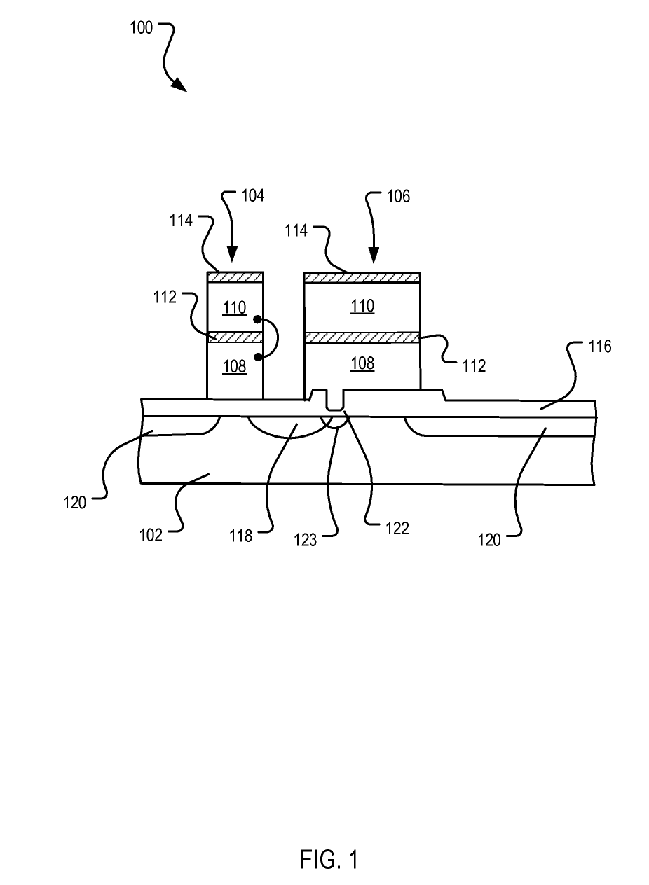

FIG. 1 is across-sectional view of a self-aligned non-volatile memory cell (“memory cell”) 100. The memory cell 100 has a semiconductor substrate 102. The semiconductor substrate 102 can be silicon or any other appropriate semiconductor material.

In some implementations, the memory cell 100 can be manufactured as a p-type memory cell. Each memory cell 100 can include a select transistor 104 and a memory transistor 106. The select transistor 104 and memory transistor 106 can include a first poly 108 and a second poly 110 that are separated by an interpoly dielectric layer 112. The first poly 108 in the memory transistor 106 can be a floating gate, while the second poly 110 can be a control gate for the select transistor 104 and memory transistor 106. In some implementations, the first poly 108 and second poly 110 of the select transistor 104 can be connected, as shown, so that the select transistor 104 functions as a single gate transistor, rather than a floating gate transistor.

A second dielectric layer 114 can be formed on the second poly 110 of the select transistor 104 and memory transistor 106. The first poly 108 and the second poly 110 can be formed, for example, from polysilicon, or any other appropriate gate material. The interpoly dielectric layer 112 and the second dielectric layer 114 can be formed, for example, from oxide-nitride-oxide or any other appropriate dielectric layer.

In some implementations, the first poly 108 and second poly 110 can be positioned on a structured oxide layer 116. A source 118 and drains 120 can be defined in the semiconductor substrate 102 for the select transistor 104 and the memory transistor 106. In some implementations, the source 118 and drains 120 are defined, for example, with p-regions that are implanted in an n-type semiconductor substrate, resulting in a p-type memory cell.

The structured oxide layer 116 can be, for example, silicon dioxide or any other appropriate oxide layer. The structured oxide layer 116 can have a thickness that varies from approximately 19 Å to approximately 280 Å and defines a tunnel 122. Other dimensions can also be used, depending on the application and design criteria. The tunnel 122 can be positioned, for example, over an n+ implant region 123.

### II. Tunnel Window

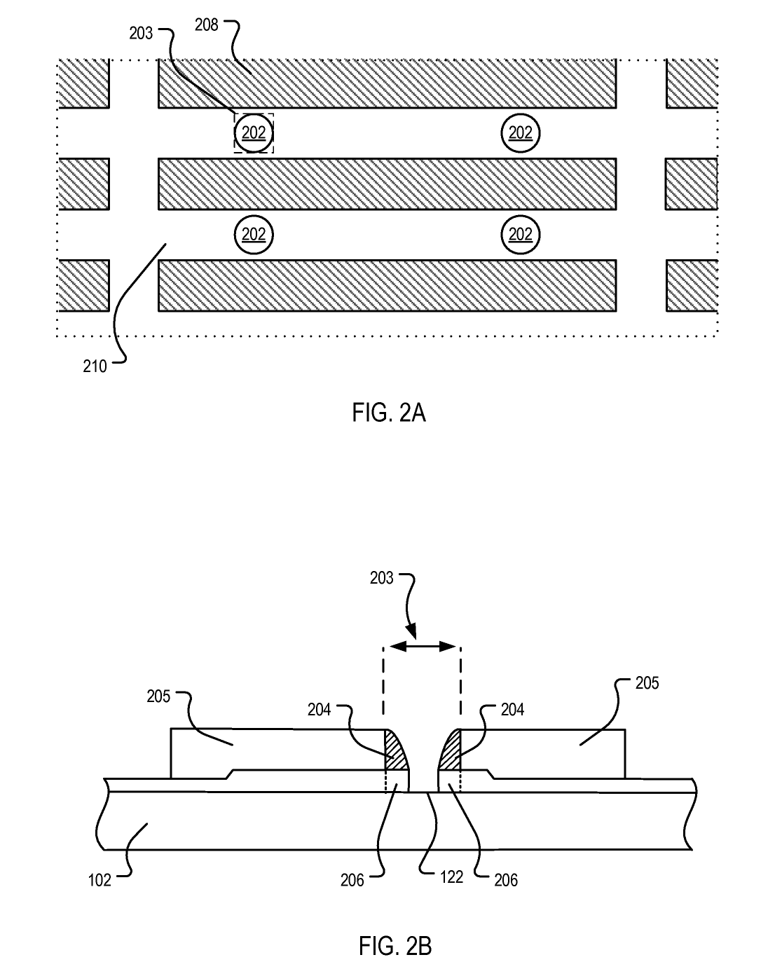

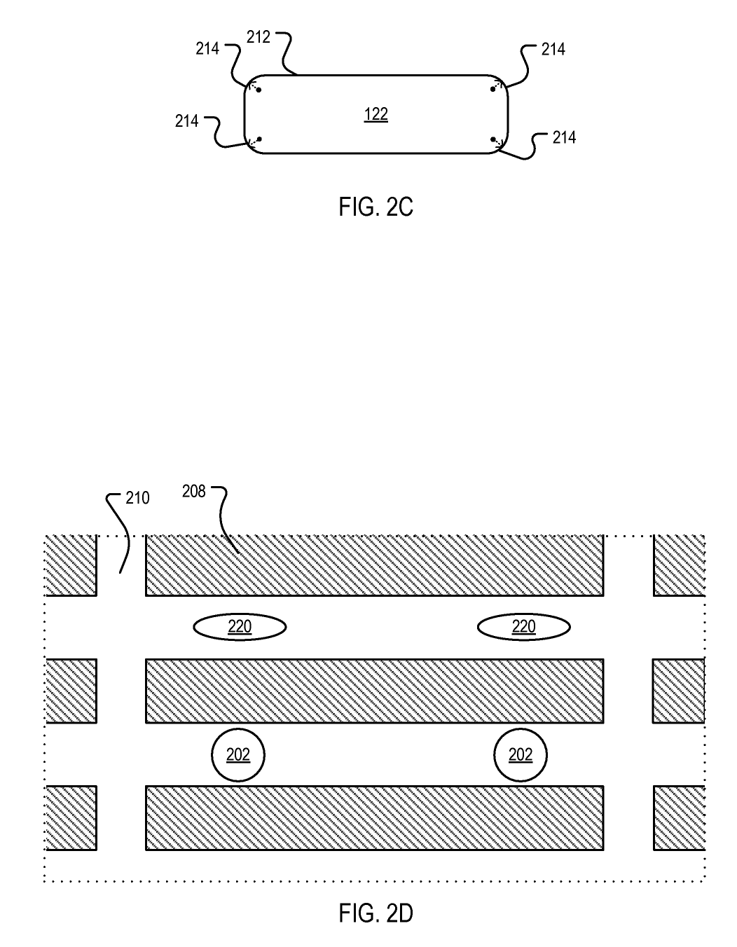

FIG. 2A is a top view of the semiconductor substrate 102. The substrate has tunnel windows 202. The semiconductor substrate 102 can have isolation regions 208 and active regions 210. Isolation regions 208 can be formed in the semiconductor substrate using shallow trench isolation (STI), local oxidation of silicon, or any other appropriate isolation technique. The active regions 210 can be defined as the areas of the semiconductor substrate 102 that are between the isolation regions 208. In some implementations, the tunnel windows 202 can be defined completely within the active areas 210.

The size of the tunnel windows 202 impacts the scaling of the memory cell 100 because required gate dimensions are proportional to tunnel window dimensions. In some implementations, the size of tunnel windows 202 can be scaled by forming circular tunnel windows 202, as illustrated in FIG. 2A, rather than square or rectangular tunnel windows. Circular tunnel windows 202 can be formed, for example, by using a square mask opening that does not include optical proximity correction (OPC).

OPC is typically used to correct for photolithography errors that occur due to light bending as it propagates. For example, using a mask with a square opening that includes OPC will result in a square photoresist opening having an edge length l. However, using a mask with a square opening that does not include OPC results in a circle photoresist opening having a diameter d approximately equal to l. Similarly, the corners of a rectangular mask opening will be rounded without the use of OPC. Accordingly, to produce tunnel windows having rounded corners, or that are circular or rounded in shape, masks having square openings that lack OPC can be used.

The area of a circle having a diameter equal to X is smaller than the area of a square having an edge length equal to X. For example, the area of the circular tunnel window 202 will be π(d/2)̂2, while the square tunnel window will have an area equal to l̂2. Therefore, tunnel windows with rounded corners or one or more curvatures can be used to scale a memory cell beyond that possible using tunnel windows with squared corners. In turn, the dimensions of the active region and gates can be proportionately scaled.

For example, a circular tunnel window 202 with a diameter of 0.1 um will have an area of 0.007850 um, while a square tunnel window having an edge length of 0.1 um will have an area of 0.01 um. In turn, the size of the gates and active areas that utilize circular tunnel windows can be reduced in proportion to the size of the tunnel window, thereby resulting in smaller scale memory cells.

In some implementations, the tunnel window can be further scaled by reducing the energy of the light used to define the pattern in the photoresist. For example, a light having approximately 300 milijoules (mJ) of energy can be used to define a pattern in photoresist. However, if the energy is reduced below 300 mJ then the area of the defined pattern will be smaller. Accordingly, using lower energy light can result in further scaling of the tunnel window. In some implementations, light having 200-400 mJ of energy can be used to define the tunnel window. While an example energy range has been provided, the light energy can vary beyond the example energy range based on the equipment used and/or the application.

In some implementations, the tunnel 122 can be further scaled by using spacers 204, as illustrated in FIG. 2B. For example, spacers 204 can be deposited in the opening 203 created in the photoresist 205 prior to etching the tunnel 122. The spacers can be formed, for example, from low pressure chemical vapor deposition, or any other appropriate spacer material.

The spacers 204 can prevent the oxide 206 located beneath the spacers 204 from being etched during creation of the tunnel 122. Accordingly, the resulting tunnel will be smaller than that realized, for example, with photolithography alone. In turn, the gates can be further scaled in proportion to the reduced area of the tunnel 122. Table 1 below provides example scaling that can be achieved using spacers 204.

TABLE 1

| Spacer | Mask | Tunnel | Mask | Tunnel |
|---|---|---|---|---|
| Thickness | .18 × .18 um | Area | .15 × .15 um | Area |
| (Å) | Area (nm)\hat{ }2 | (nm)\hat{ }2 | Area (nm)\hat{ }2 | (nm)\hat{ }2 |
| 200 | 25600 | 15393.79 | 16900 | 9503.31 |
| 300 | 22500 | 11309.72 | 14400 | 6361.72 |
| 400 | 19600 | 7853.98 | 12100 | 3848.45 |
| 500 | 16900 | 5026.54 | 10000 | 1963.49 |
| 600 | 14400 | 2827.43 | 8100 | 706.86 |
| 700 | 12100 | 1256.64 | 6400 | 78.54 |

The tunnel window size can also impact the reliability and operating performance of a scaled memory cell 100. For example, the use of a tunnel window can affect the leakage current experienced by the memory cell 100. Referring again to FIG. 2A, leakage current can be caused, for example, by degradation of the oxide layer due to stresses experienced near a shallow trench isolation region (STI) region 208 formed in the semiconductor substrate. The circular tunnel window 202 can reduce the leakage current of a memory cell. To illustrate, a phantom square tunnel window 203 is superimposed over a circular tunnel window 202. The leakage current can be reduced, for example, because the portion of a circular tunnel window 202 that is closest to the edge of the active region 208 is less than the portion of the phantom square tunnel window 203 that is closest to the edge of the active region 208. For example, when the phantom square tunnel window 203 is defined, the entire length of an edge is approximately the same distance from the edge of the active region. In contrast, when a circular tunnel window is used, only a tangential portion of the tunnel window is closest to the edge of the active region. Accordingly, the current leakage associated with a circular tunnel window a minimum distance from the edge of the active region will have lower leakage current than a square tunnel window the same distance from the edge of the active region.

The leakage current of the memory cell 100 also increases as the temperature of the device increases. Accordingly, devices that have higher leakage currents will have lower operating temperature ranges because of the increased leakage current at higher temperatures. A smaller tunnel window can thus increase the distance between the tunnel window and the STI region 208, thereby lowering the leakage current. Accordingly, in some implementations, increasing the reliability and operating performance of the memory cell 100, while scaling the memory cell 100, can be achieved by reducing the area of the tunnel window and positioning the tunnel window completely within an active region 210.

In some implementations, a scaled tunnel window can facilitate scaling of the active regions 210. For example, once a sufficient distance from the STI region 208 is achieved, such that a maximum leakage current requirement is satisfied, additional scaling of the tunnel window 202 can enable proportional scaling of the active region, while still satisfying the maximum leakage current specified.

While tunnel windows having perimeters defining circles have been provided for example purposes, any tunnel perimeter that defines one or more curvatures can be used. For example, FIG. 2C is a top view of an example tunnel 122 having a perimeter 212 that defines curvatures 214. The tunnel 122 can also be formed having non-symmetrical properties. For example, each of the curvatures can be formed having a different respective radius. Similarly, the distance between pairs of adjacent curvatures 214 can vary.

FIG. 2D is another top view of a semiconductor substrate having tunnel windows. As shown, circular tunnels 202 or elliptical tunnels 220 can be positioned completely within the active region 210 of the semiconductor substrate. Similar to a circular tunnel 202, an elliptical tunnel 220 will have an area that is smaller than a rectangular tunnel having the same length and width. Additionally, the position of the elliptical tunnel 220 can reduce leakage current associated with the increased stress near the STI regions 208. The leakage current can be reduced over square and circular tunnels 202 because the area of the elliptical tunnel 220 can be located further from the STI regions 208. For example, an elliptical tunnel 220 having the same area as a circular tunnel 202 can be positioned so that the larger length associated with the elliptical tunnel 220 is parallel to the STI region 208, as shown in FIG. 2D. Accordingly, the distance between the edge of the elliptical tunnel 220 and the STI region 208 can be larger than the distance between the edge of a circular tunnel 202 of the same area and the STI region.

### III. Example Memory Cell Fabrication

i. Oxide Formation

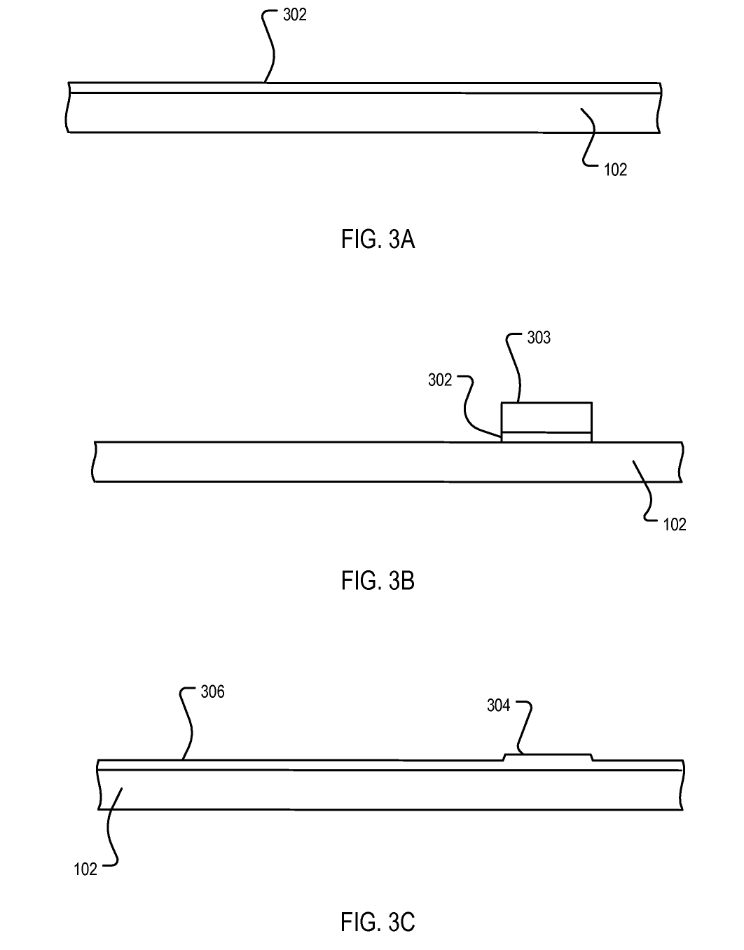

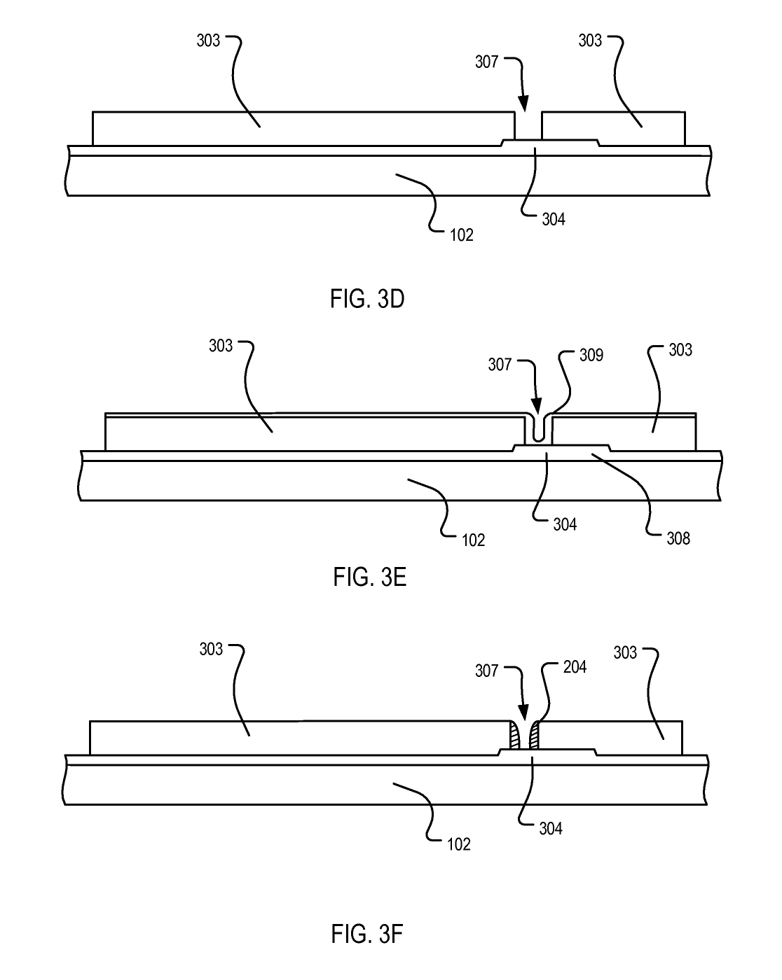

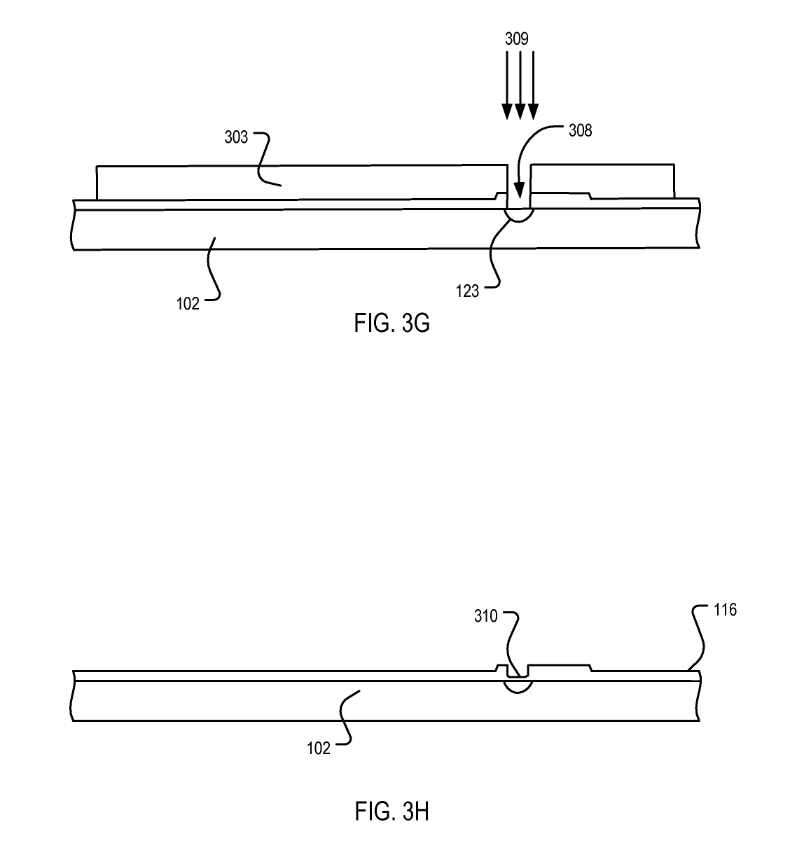

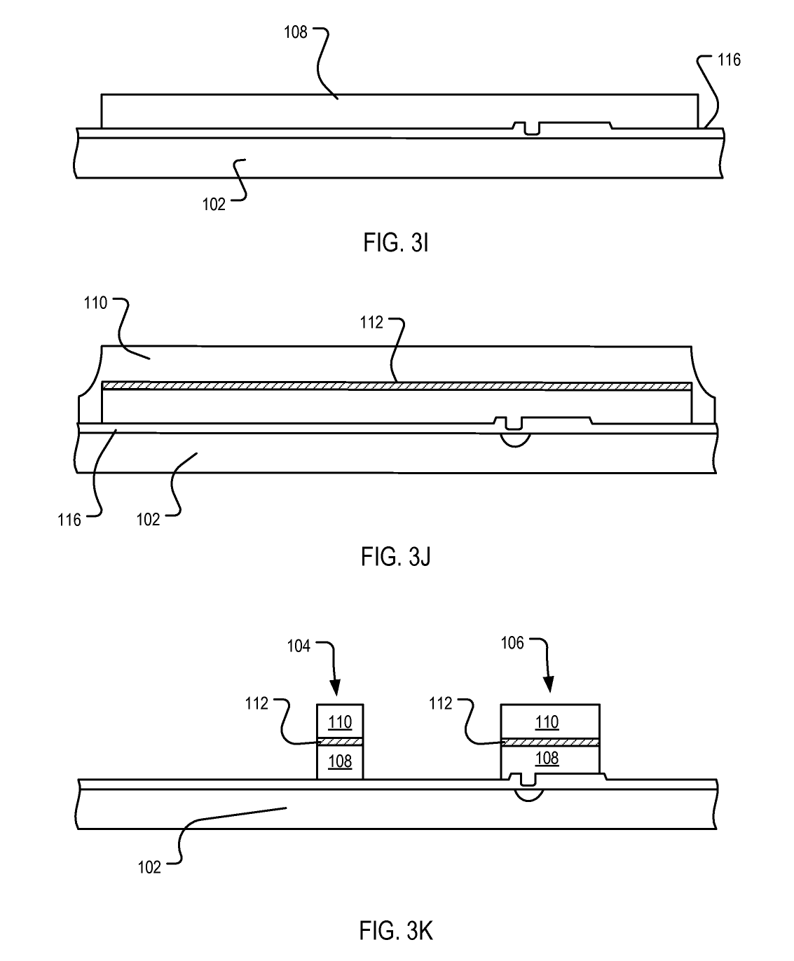

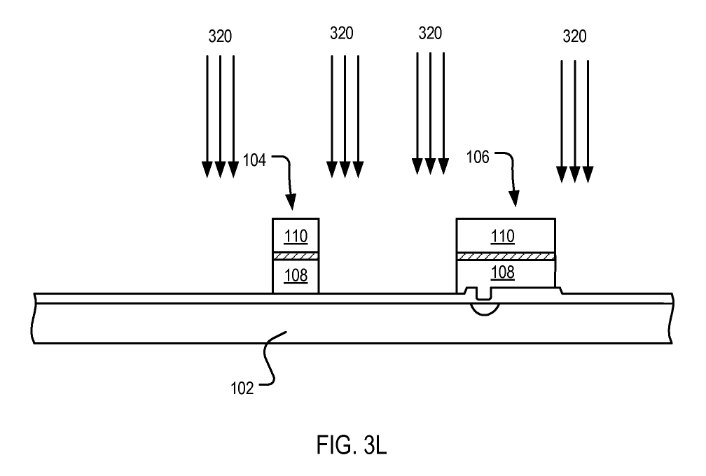

FIGS. 3A-3L are cross-sectional views of an example memory cell at stages throughout an implementation of self-aligned non-volatile cell fabrication. An initial oxide layer 302 can be grown on the semiconductor substrate 102, as shown in FIG. 3A. The initial oxide layer 302 can be silicon dioxide or any other appropriate oxide layer. The initial oxide layer 302 can be formed, for example, by thermal oxidation of the semiconductor substrate 102 or any other appropriate method. The initial oxide layer 302 can be grown, for example, to be approximately 250 Å-400 Å thick.

Photoresist 303 can be applied to a portion of the initial oxide layer 302 where the memory transistor will be located, as shown in FIG. 3B. A mask can be used to selectively apply the photoresist 303 to the initial oxide layer 302. Once the photoresist 303 is applied, the initial oxide layer 302 is etched. The etching process removes the initial oxide layer 302 that is not protected by the photoresist 303. The photoresist is then removed from the remaining initial oxide layer 302.

A second oxide layer 306 can be grown on the semiconductor substrate 102. The second oxide layer 306 can also be grown on the remaining initial oxide layer 302 to create a raised oxide portion 304, as shown in FIG. 3C. The second oxide layer 306 grows at a slower rate on the initial oxide layer 302 than it does on the semiconductor substrate 102. Accordingly, the second oxide layer 306 that is grown on the semiconductor substrate 102 can be approximately 220 Å thick, while the raised oxide portion 304 can be, for example, approximately 280 Å thick.

ii. Tunnel Window Definition

In some implementations, a tunnel window can be defined in the raised oxide portion 304. In these implementations, photoresist 303 can be applied to the second oxide layer 306 and the raised oxide portion 304, as shown in FIG. 3D. The photoresist protects the second oxide layer 306 and the covered portion of the raised oxide portion 304 during a subsequent etching process. In some implementations, photolithography is used to remove the photoresist 303 that is located over the raised oxide portion 304, where the tunnel window will be defined.

In these implementations, an opening 307 in the photoresist 303 can be defined using photolithography. For example, a mask can be positioned over the semiconductor substrate 102 so that a mask opening corresponding to the tunnel window is positioned over the raised oxide portion 304. The mask can be exposed to ultraviolet light. In turn, the light can propagate through the opening in the mask and define a pattern in the photoresist 303 located beneath the mask opening to expose the oxide.

In some implementations, spacer material 309 can optionally be deposited in the opening 307 that has been defined in the photoresist 303, as illustrated in FIG. 3E. The spacer material 309 can be, for example, low pressure chemical vapor deposition (LPCVD) oxide, nitride, or any other appropriate spacer material. The spacer material 309 can be etched to expose a portion of the raised oxide portion 304 and form the spacers 204, as illustrated in FIG. 3F.

After the raised oxide portion 304 is exposed by the opening 307, as illustrated in either FIG. 3D or FIG. 3F, an etching process can be used to remove the exposed portion of the raised oxide portion 304. The etching process defines a tunnel 308 in the raised oxide portion 304 that exposes the semiconductor substrate 102, as illustrated in FIG. 3G. The etching can be performed, for example, using dry etching, wet etching, or a combination of dry and wet etching. In some implementations, the tunnel 308 can be exposed to n+dopants 309 to form the tunnel n+ implant 123.

Tunnel oxide 310 can be grown on the exposed semiconductor substrate 102 and the remaining photoresist 303 can be removed. In some implementations, the tunnel oxide 310 can range from 19 Å-90 Å thick. Other thicknesses can also be used, depending on the application. An example of a completed structured oxide layer 116 is shown in FIG. 3H.

iii. Gate Formation

In some implementations, after the structured oxide layer 116 is complete, a first poly layer 108 is deposited on the structured oxide layer 116, as shown in FIG. 3I. The first poly layer 108 can be polysilicon or any other appropriate conductive gate material. The first poly layer 108 can form, for example, the floating gates of the memory cell.

A interpoly dielectric layer 112 can be formed on top of the first poly layer 108 and a second poly layer 110 is deposited on the interpoly dielectric layer 112, as shown in FIG. 3J. The interpoly dielectric layer 112 can be, for example, oxide-nitride-oxide or any other appropriate dielectric. The second poly layer 110 can be, for example, polysilicon or any other appropriate conductive gate material.

In some implementations, the first poly layer 108 and the second poly layer 110 can both be etched in a single etching process to form gates for the select transistor 104 and memory transistor 106, as shown in FIG. 3K. The resulting select transistor 104 and memory transistor 106 will have defined floating gates (e.g., first poly layer 108) and control gates (e.g., second poly layer 110). In some implementations, the first poly layer 108 and the second poly layer 110 that form the gates for the select transistor 104 can be connected. This enables the select transistor to operate as a single gate transistor.

In some implementations, the first poly layer 108 can be etched prior to deposition of the second poly layer 110 to form the floating gates. In these implementations, the second poly layer 110 can be deposited on the semiconductor substrate 102 and the interpoly dielectric layer 112 that is deposited on the first poly layer 108.

iv. Source and Drain Definition

Source 118 and drain 120 definition can be performed by adding dopants 320 to the semiconductor substrate 102, as shown in FIG. 3L. In some implementations, the memory cell 100 can have a source 120 that is common to the select transistor 104 and memory transistor 106, as shown in FIG. 1.

In some implementations, a source 118 and drains 120 are formed after the gates 108, 110 have been formed to create self-aligned gates. When the source 118 and drains 118 are formed after gate formation, dopants can be added to the semiconductor substrate 102, for example, at a position adjacent to the select transistor 104 and memory transistor 106, respectively. The dopants can be added by ion implantation or any other appropriate method for adding dopants to a semiconductor substrate 102. In these implementations, the gates 108, 110 of the select transistor 104 and memory transistor 106 function as masks to prevent dopants from being added to the semiconductor substrate 102 beneath the respective gates 108, 110. Accordingly, the select transistors 104 and the memory transistors 106 are self-aligned transistors.

### IV. Example Process Flow

i. Manufacturing a Non-Volatile Memory Cell

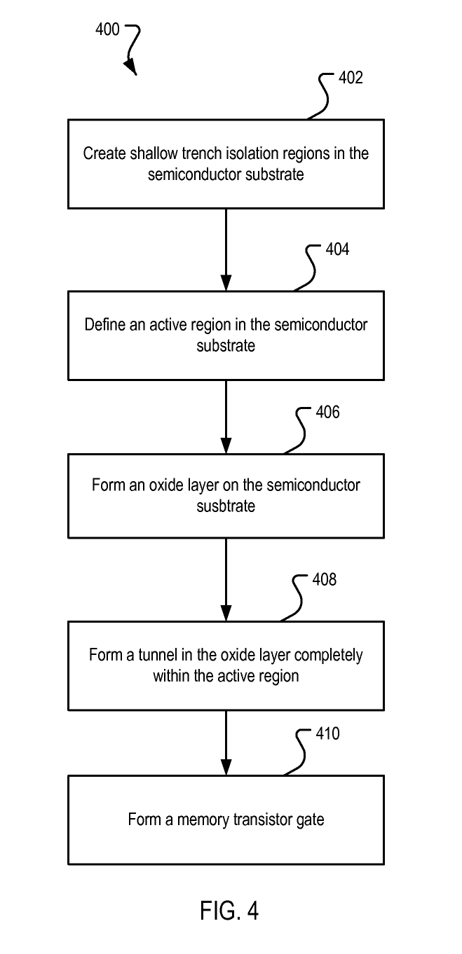

FIG. 4 is a flow chart illustrating an example process of manufacturing a non-volatile memory cell. At stage 402 the process 400 can create shallow trench isolation regions in the semiconductor substrate. The shallow trench isolation regions can be created, for example, by etching the semiconductor substrate to create trenches. The trenches can be filled with a dielectric material (e.g., silicon dioxide). The dielectric material can then be planarized to remove any dielectric material that is outside the isolation regions and create a level surface on the semiconductor substrate.

Stage 404 defines active regions in the semiconductor substrate. The active regions can be defined by the isolation regions. For example, the areas between adjacent isolation regions can be defined as the active regions.

Stage 406 forms an oxide layer on the semiconductor substrate. In some implementations, the oxide layer can have a substantially uniform thickness. In some implementations, the oxide layer can have a raised oxide portion. The oxide layer can be formed, for example, by growing a first oxide layer, etching the first oxide layer to define the raised oxide portion, and growing a second oxide layer. In some implementations the oxide can be grown through a thermal oxidation process.

Stage 408 forms a tunnel in the oxide layer completely within the active region. In some implementations, the tunnel can have a perimeter that defines one or more curvatures. The tunnel can be formed, for example, by defining the tunnel with photolithography and growing a tunnel oxide layer in the defined tunnel. In some implementations, the tunnel can be defined using a photolithography mask having a square opening.

Stage 410 forms a memory transistor gate. The memory transistor gate can be formed on top of the tunnel. In some implementations, the memory transistor gate can be a self-aligned memory gate. In some implementations, a self-aligned select transistor gate can also be formed on the oxide layer. The self-aligned select transistor gate and self-aligned memory transistor gate can each be formed by depositing polysilicon on the semiconductor substrate, etching the polysilicon to define the gates, and adding dopants to the semiconductor substrate. In some implementations, the gates function as a mask to prevent the dopants from being added to the semiconductor substrate beneath the gates. The memory transistor gate can include a floating gate. In some implementations, the select transistor gate can include a floating gate structure that is connected to a control gate.

ii. Forming a Tunnel Window

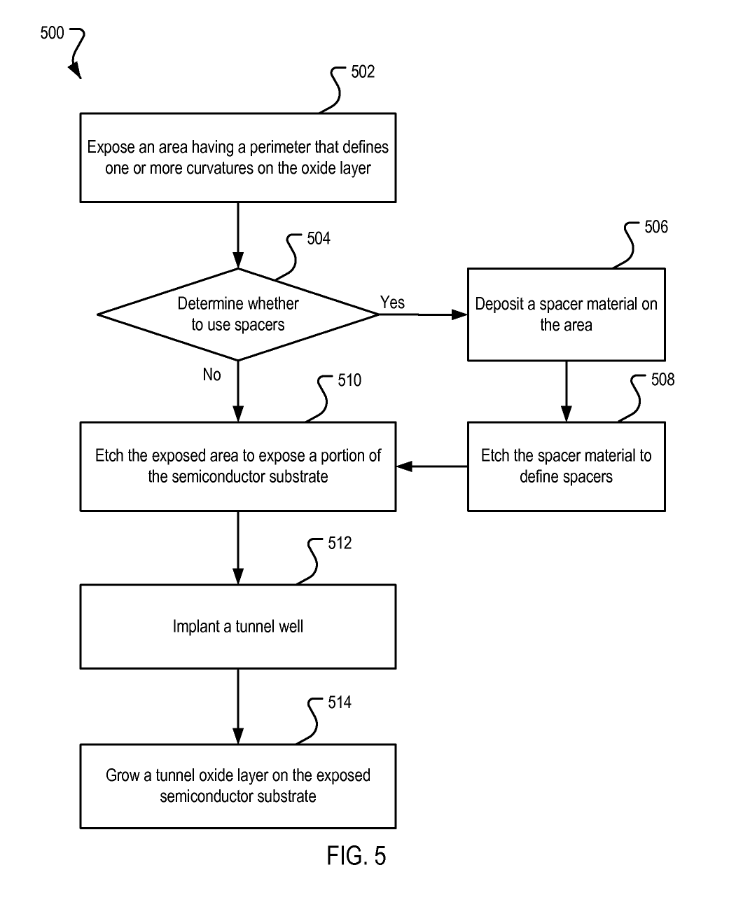

FIG. 5 is a flow chart illustrating an example process 500 of forming a tunnel window having rounded edges. The process 500 can begin at stage 502 by exposing an area having a perimeter that defines one or more curvatures on the oxide layer. The area can be exposed, for example, using photolithography or any other appropriate process for isolating a portion of oxide for processing. In some implementations, the area can be defined using a square photolithography mask.

Stage 504 determines whether spacers will be used to scale the area formed in stage 502 beyond the scaling achieved using photolithography alone. If it is determined that spacers will be used, then the process can continue to stage 506. If it is determined that spacers will not be used, then the process can continue to stage 510. While the determination is presented as occurring after stage 502, the determination can be made at any time (e.g., prior to performance of stage 502). Stage 504 is presented after stage 502 to simplify illustration of the process.

If spacers will be used, stage 506 can deposit a spacer material on the area. The spacer material can be formed, for example, with a low pressure chemical vapor deposition, oxide, or nitride.

Stage 508 etches the spacer material to define spacers. In some implementations, the spacer material is etched to expose a circular portion of the semiconductor substrate. Accordingly, the spacer material can be disposed along the circumference of the area, thereby scaling the exposed area of the oxide layer.

Stage 510 etches the exposed area to expose a portion of the semiconductor substrate. In some implementations, spacers are used. Accordingly, the exposed area that is etched will be scaled relative to the area that is initially exposed. In other implementations, spacers are not used. Accordingly, the exposed area that is etched will correlate with the area that is initially exposed. In some implementations, the area can be etched using a combination of dry etching and wet etching.

Stage 512 implants a tunnel well. The tunnel well can be implanted, for example, in the exposed portion of the semiconductor substrate. In some implementations, the tunnel well can be formed by implanting n+dopants into the semiconductor substrate. However, other types of dopants can be used according to the application and the device being formed.

Stage 514 grows a tunnel oxide layer on the exposed semiconductor substrate. In some implementations, the tunnel oxide layer can be grown for example through a thermal oxidation process. The thermal oxide can be grown, for example, to have a thickness in a range of about 19 Å-90 Å.

While this document contains many specific implementation details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while process steps are depicted in the drawings in a particular order, this should not be understood as requiring that such process steps be performed in the particular order shown or in sequential order, or that all illustrated process steps be performed, to achieve desirable results.

Particular embodiments of the subject matter described in this specification have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results.

What is claimed is:

1. A method, comprising:
defining an active region in a semiconductor substrate;
forming an oxide layer on the semiconductor substrate;
forming a tunnel in the oxide layer within the active region, the tunnel having a perimeter defining one or more curvatures; and
forming a memory transistor gate on the tunnel.

2. The method of claim 1, wherein defining the active region in the semiconductor substrate comprises creating shallow trench isolation regions in the semiconductor substrate, and wherein the active region is defined by adjacent shallow trench isolation regions.

3. The method of claim 1, wherein the perimeter defines a circular circumference.

4. The method of claim 1 wherein forming the tunnel in the oxide layer comprises:
exposing an area having a perimeter that defines one or more curvatures on the oxide layer;
etching the exposed area to expose a portion of the semiconductor substrate; and
growing a tunnel oxide layer on the exposed semiconductor substrate.

5. The method of claim 4, further comprising forming spacers on the exposed raised oxide portion.

6. The method of claim 5, wherein forming spacers on the exposed raised oxide portion comprises:
depositing a spacer material on the area; and
etching the spacer material to define spacers that are disposed along the perimeter of the area.

7. The method of claim 6, wherein the spacer material comprises a low pressure chemical vapor deposition.

8. The method of claim 4, wherein exposing an area having a perimeter that defines one or more curvatures on the oxide layer comprises:
depositing photoresist on the oxide layer; and
defining a perimeter having one or more curvatures in the photoresist over the oxide layer.

9. The method of claim 8, wherein defining a perimeter having one or more curvatures comprises exposing the photoresist to a light having a defined energy, and wherein the perimeter having one or more curvatures is scaled according to the defined energy.

10. The method of claim 9, wherein the defined energy is within a range of about 200 milijoules to about 400 milijoules.

11. The method of claim 1, wherein forming the oxide layer comprises:
growing a first oxide layer on the semiconductor substrate;
etching the first oxide layer to define a raised oxide portion; and
growing a second oxide layer on the semiconductor substrate and the remaining first oxide layer.

12. The method of claim 1, wherein forming a tunnel comprises forming a rounded tunnel.

13. The method of claim 12, wherein forming a rounded tunnel comprises defining a circular tunnel window with a square mask opening.

14. The method of claim 1, wherein forming a memory transistor gate comprises forming a self-aligned memory transistor gate.

15. A non-volatile memory cell, comprising:
a semiconductor substrate having an active region;
an oxide layer formed on top of the semiconductor substrate;
a tunnel defined in the oxide layer and positioned within the active region, wherein the tunnel has a perimeter that defines one or more curvatures; and
a gate structure formed on top of the tunnel.

16. The non-volatile memory cell of claim 15, wherein the gate structure comprises a self-aligned gate structure, and wherein the gate structure comprises a floating gate and a control gate associated with a memory transistor.

17. The non-volatile memory cell of claim 16, further comprising a first poly layer deposited on the semiconductor substrate and a second poly layer deposited on top of the first poly layer, wherein the first poly layer and second poly layer are associated with a select transistor, and wherein the first poly layer and the second poly layer are connected.

18. The non-volatile memory cell of claim 15, wherein the active region is defined by adjacent isolation regions formed in the semiconductor substrate.

19. The non-volatile memory cell of claim 15, wherein the tunnel has a circular perimeter.

20. The non-volatile memory cell of claim 15, further comprising a spacer disposed along the perimeter of the tunnel.

21. The non-volatile memory cell of claim 20, wherein the spacer comprises a low pressure chemical vapor deposition.

22. A method of fabricating a non-volatile memory cell, comprising:
creating isolation regions in a semiconductor substrate, wherein adjacent isolation regions define an active region in the semiconductor substrate;
forming an oxide layer having a raised oxide portion on the semiconductor substrate;
forming a tunnel having a circular circumference in the raised oxide portion, wherein the tunnel is defined within the active region; and
forming a self-aligned select transistor gate and a self-aligned memory transistor gate on the oxide layer, wherein the memory transistor gate is formed on top of the tunnel.

23. The method of claim 22, wherein forming the tunnel comprises:
exposing a rounded area of the raised oxide portion;
etching the rounded area to expose a circular portion of the semiconductor substrate; and
growing a tunnel oxide layer on the exposed semiconductor substrate.

24. The method of claim 23, further comprising forming spacers on the rounded area of the raised oxide portion.

25. The method of claim 24, wherein forming spacers on the rounded area of the raised oxide portion comprises:
depositing a spacer material on the rounded area of the raised oxide portion; and
etching the spacer material to form spacers that are disposed along the circumference of the rounded area of the raised oxide portion.
